(19) United States
(12) Patent Application Publication
(10) Pub. No.: US 2009/0288854 A1
(43) Pub. Date: Nov. 26, 2009

(54) Apparatus for positive, low-cost scalding prevention for hot water heaters

(76) Inventors: Benjamin Leeds, Los Angeles, CA (US); Susan L. Kudo, Pacific Palisades, CA (US)

Correspondence Address: Abraham N. Seidman, P.O. Box 16603, Beverly Hills, CA, 90209, US

(21) Appl. No.: 12/154,070

(22) Filed: May 20, 2008

(51) Int. Cl. H05K 5/03

(52) U.S. Cl. 174/67

(57) ABSTRACT

This invention provides a low-cost, life-saving, scalding protection against an unwanted change, in the temperature control knob on a hot-water heater. It is simple to install and operate, so as to invite apartment owners and operators to readily install this scald-prevention apparatus. It does not wear-out over time nor does it require maintenance. It is a box-like structure, with a hinged cover and a hinged closing hasp, fitting over a staple, allowing the apparatus to be pad-locked. It has a “bottom” cutout fitting over the hot-water heater temperature control knob, and is attached with ordinary screws, the heads of which are enclosed by the protective shell.

### FIELD OF THE INVENTION

This invention relates to prevention of scalding from hot-water heaters by preventing the control setting from being inadvertently or purposefully reset from a safe temperature setting.

### BACKGROUND OF THE INVENTION

Unintentional scalding from too-hot tap water is the second largest source of serious bums in the United States. Over two thousand serious bum cases of children, resulting from tap-water scalding, require hospitalization or similar treatment, per year, in the residential households in the United States. There is an eminent need for simple, low-cost devices to prevent these disastrous situations from arising. So far, the main attack on these bum cases has required plumber installed anti-scald thermostatic mixing valves, which require additionally a cold -water feed and an in-line filter upstream of the thermostatic mixing valve.

Another approach has been to use an automatic pressure compensating valve, to hold the temperature within a certain number of degrees of the original temperature for the valve setting.

Both of these approaches require an extensive retrofitting of plumbing fixtures, expensive, and unlikely to be implemented by apartment owners, in the absence of new laws or building regulations. Meanwhile, children and adults are continuing to be scalded, unnecessarily.

Furthermore, these plumbing solutions are subject to failure, and in general require access and maintenance on an ongoing basis.

There is still a need for a simple, inexpensive device which will prevent unnecessary scalding burns. This need for a simple safety device need has existed for a long time and is still unmet, until now.

The invention described below utilizes a simple to install locked covering. Lock boxes, such as U.S. Pat. No. 3,934,434 do not provide a mechanism to enclose the control device. Control protectors such as U.S. Pat. No. 4,055,724 are complex and expensive. Also, these control covers are set up for controls which need to be changed from time-to-time and they are not heavy-duty, rugged devices.

### SUMMARY OF THE INVENTION

This invention comprises a heavy duty protective shell made from, for example, steel, which is predrilled for attachment over large hot-water heater temperature controls, and has a lockable hinged access cover. It can be simply installed, for example, with heavy duty self-tapping metal screws, which can be of any type, since they are also covered by the protective shell, when the access cover is locked. The box-like protective shell has an opening on its underside which has been pre-cut out to allow the hot-water heater control to penetrate into the interior of the protective shell and allows the protective shell to be installed closely to the hot water heater without an easily penetrated gap, which might otherwise allow the penetrative shell to be pried loose. The locking means can be of any type, such as a padlock, where the hinged closure of the apparatus may be fitted with a hasp and staple arrangement. One or more windows may be included in the protective shell, allowing viewing and verification of the control setting without opening the hinged access cover. A first window for viewing the control may be supplemented by second window, set in a side of the protective shell, in order to allow ambient light or light from a flashlight to better illuminate the control. The window(s) may be made of acrylic or other transparent plastic, of sufficient strength and thickness, so as to prevent an easy location to break into the protective apparatus. Any other suitable transparent material may be used, such as ballistic glass.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows an exemplary best mode version of the apparatus, without windows;

FIG. 2 shows an exemplary best mode version of the apparatus with one window;

FIG. 3 shows an exemplary best mode version of the apparatus with two windows;

FIG. 4 shows the cross-section AA of FIG. 2;

FIG. 5 shows the cross-section of BB of FIG. 3;

FIG. 6 shows details of the hinge for the protective shell;

FIG. 7a shows details of the bent hinged hasp, with a curved tip;

FIG. 7b shows details of the bent hinged hasp, with a non-curved tip;

FIG. 8 shows the corresponding staple which in conjunction with the hasp allow for padlocking the hinged cover;

FIG. 9 shows a bottom view with 4 holes for screws and one large cutout for a hot-water heater thermostat control; and

FIG. 10 shows the relative placement of the apparatus on an exemplary water heater (water heater not part of this invention).

### DETAILED DESCRIPTION OF THE BEST MODES

The following description is of the best mode presently contemplated for carrying out the invention. This description is not to be taken in a limiting sense, but is merely made for the purpose of describing the general principles of the invention.

In the following description and in all of the cited figures, no part of a hot-water heater is part of the invention.

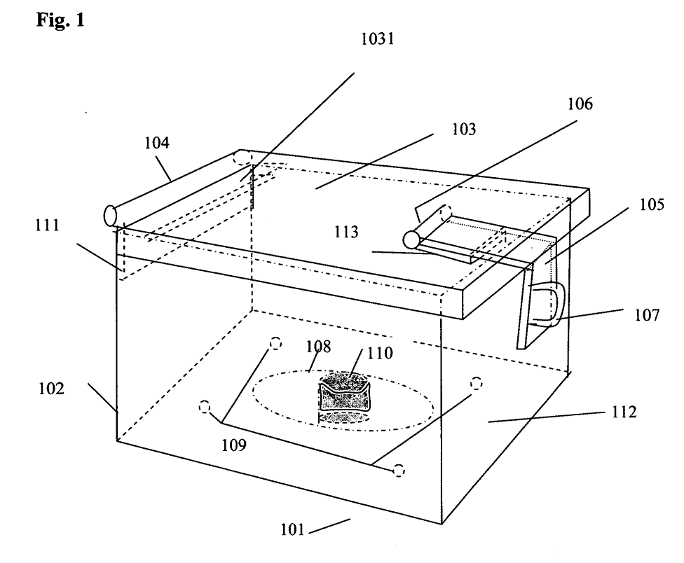

FIG. 1 shows an embodiment of the invention 101. The main body 102 of the protective shell is a rectangular three-dimensional box-like structure. There is a cut-out 108 on the bottom 112 of the box 102. This cutout is larger than the hot-water thermostat (temperature) control 110 (not a part of this invention). The cut-out 108 is made larger than the temperature markings on the hot-water heater. These markings are typically ser on a two (2) inch diameter circle. Thus, an embodiment of a three (3) inch cut-out 108 serves to include the hot-water heater temperature markings within a visible region. A range of cut-out diameters range from a minimum of about 2.25 inches to a maximum set by the minimum horizontal dimensions of the bottom 112 of the protective shell 102, consistent with maintaining the strength of the protective shell 102 and the invention 101.

Four screw holes 109 are shown in a best mode embodiment. The diameter of the screws are ¼ inches and may range from a diameter of ½ inches maximum to a minimum of ⅛ inches, consistent with a holding force of fastening means such as screws or bolts sufficient to defeat an attempt to pull off the box. The embodiment shown is suitable for ¼ inch self-tapping metal screws. Because the screw heads are located within the protective shell, there is no need for “safety” screws which can only be screwed in (easily) and not easily unscrewed.

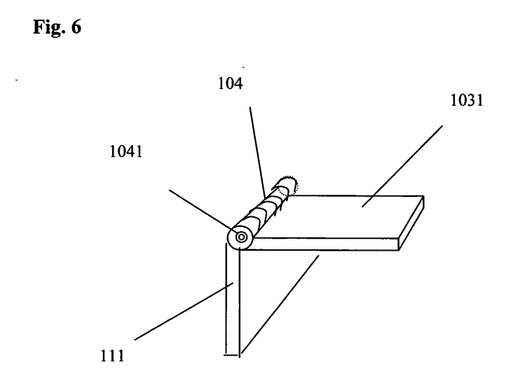

The embodiment shows a hinged cover 103 which has a hinge 104 attached on a first end of the cover 103 by a second hinge plate 1031. The hinge 104 is attached to the box 102 with a first hinge plate 111. The detail of the hinge 104 with a first hinge plate 111 and a second hinge plate 1031 is further shown in FIG. 6, the hinge 104 being of a “piano” type, with an internal 104 (FIG. 6, 1041). The preferred method of attachment of a first hinge plate 111 (FIG. 1) to the protective shell 102 is by welding. The preferred attachment method of a second hinge plate 1031 to the cover 103 is welding.

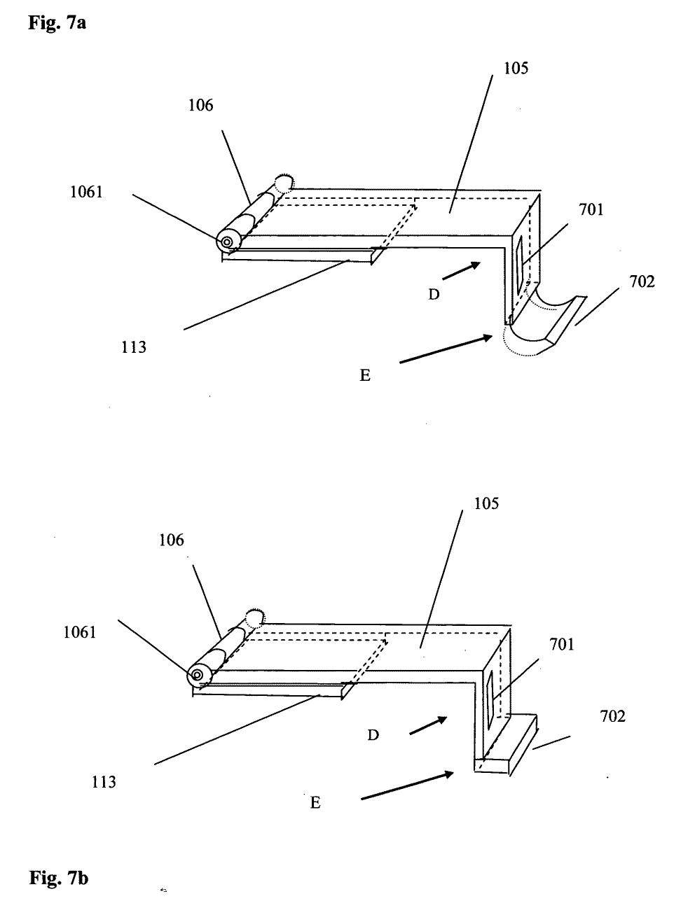

The fastening mechanism comprises a hinged 106 hasp 105 which is adapted to fit over a staple 107 welded to the protective shell 102. The hasp 105 is secured to the cover by a first hasp hinge plate 113. Detail of the hasp 105 (which acts as a second hasp hinge plate 105) is shown in FIGS. 7a and 7b.

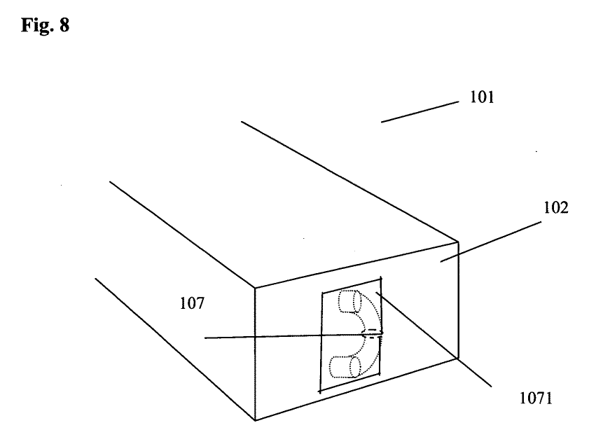

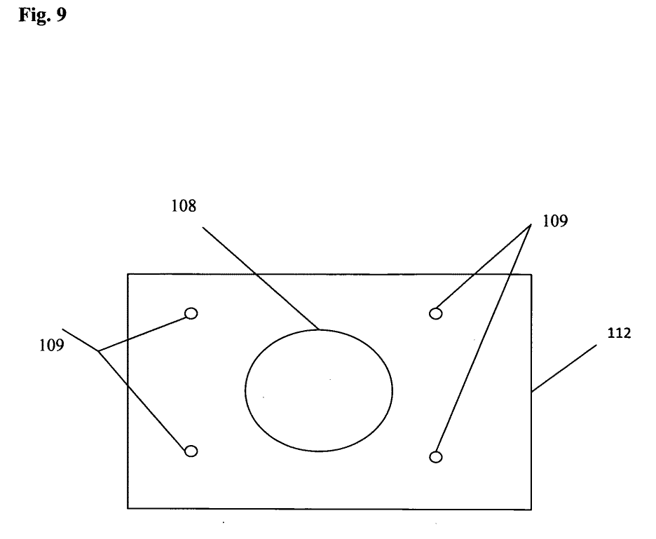

FIG. 7a shows an ordinary, straight, hinged-hasp 105 bent at D and roundedly bent at E, so as to provide a conformal (to the cover 103 and the protective shell 102) locking system, which may be completed by a padlock (not part of this invention) engaged through the staple 107. The roundedly bent (at E) portion eases the closing of the hasp over the upper, forward edge of the protective shell 102 and provides a gripping feature, adapted to ease the opening and closing of the hasp 105 and staple 107 (FIG. 8, “detail”). The slot 701 (FIG. 7a) in the hasp 105 engages the staple 107 (FIG. 8) when the cover 103 (FIG. 1) is completely closed and the hasp 105 is set to be padlocked (padlock not shown, padlock not part of this invention).

FIG. 7b shows an ordinary, straight, hinged-hasp 105 bent at D and non-roundedly bent at E, so as to provide a conformal (to the cover 103 and the protective shell 102) locking system, which may be completed by a padlock (not part of this invention) engaged through the staple 107. The non-roundedly bent (at E) portion eases the closing of the hasp over the upper, forward edge of the protective shell 102 and provides a gripping feature, adapted to ease the opening and closing of the hasp 105 and staple 107 (FIG. 8, “detail”).”). The slot 701 (FIG. 7b) in the hasp 105 engages the staple 107 (FIG. 8) when the cover 103 (FIG. 1) is completely closed and the hasp 105 is set to be padlocked (padlock not shown, padlock not part of this invention).

In FIG. 1, the hinge 106 is of a short “piano” type with a hinge plate 113 adapted to be welded to the cover 105, with a central “axis” 1061 (FIG. 7a, 7b, 1061), with the body of the hasp 105 forming a second hinge plate.

The cut-out 108 is in the range of 2.25 inches to 3.5 inches in diameter, although the upper limit could be extended to 4.5 inches.

The protective shell and the protective cover made normally made from metal, typically steel, although other materials, such as a tough, thermosetting, non-flammable plastic could also be used.

The protective shell is exemplified as formed as faces of a rectangular solid without an sixth face wherein the sixth face is opposite to the cut-out;

The dimensions of said rectangular solid ranging from 4 inches to 10 inches long, 5.inches to 8 inches wide, and 1 inch to 5 inches high. An exemplary size is 5.0 inches by 5.25 inches by 1.25 inches, without windows.

A main element of the hasp bent to shape having an end that engages the staple and then bends outward for a distance from 0.25 inches to 0.5 inches.

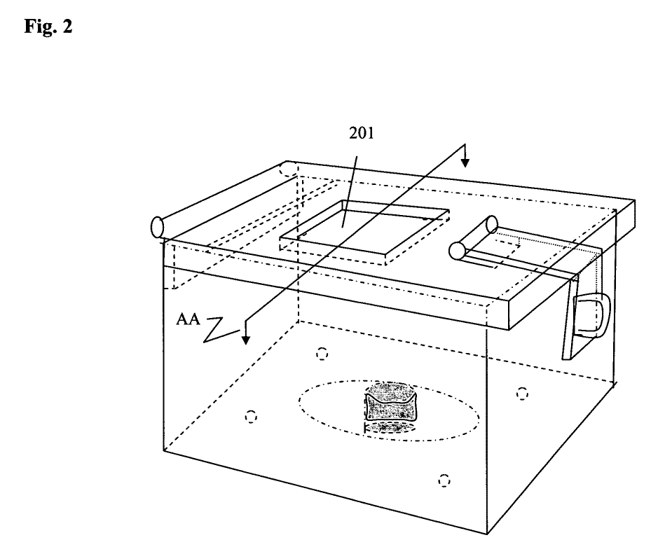

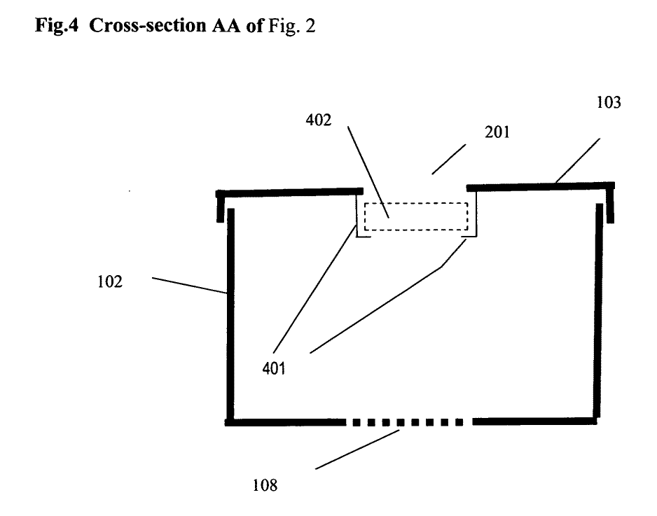

FIG. 2 shows the apparatus of FIG. 1, with the addition of a first viewing window 201, which is shown schematically as a cut-out opening 201 in the cover 103. The cross-section AA is shown in FIG. 4.

FIG. 4 shows the cut-out 201 in the cover 103, together with a protective transparent “window” material 402, such as a block of transparent acrylic plastic. A second cut-out 201 in the protective cover 103 placeably adapted to provide a view of whatever is seen through the first cut-out 108. A first transparent window 402, comprising a breakage-resistant material, is firmably held in place, by means known in the art, to cover the second cut-out from inside the protective structure formed by the protective shell 102 and the protective cover 103 The first cut-out 108 is n the range of 2.25 inches to 3.5 inches diameter.

The second cut-out 201, for the first window 402, is in the range 1 inch to 5 inches in either horizontal direction, or as a diameter, and with a first transparent window material ranging from these horizontal dimensions plus 0.25 to 0.5 inches.

The transparent window block 402 may range from ¼ inch to 1 inch of thickness. It is held in place by structural members 401, into which the block of window transparent material 402 may be slid.

The enclosing structural members 401 may be enclosing the block of window material 402 on three-sides, with a fourth enclosing member attached by screw(s) may be emplaced to secure the transparent window material 402 (adapted to be larger than the cut-out opening 201. Various methods of securing the transparent window material 402 are well known in the art and any such method may be used. This first window 402 provides for direct viewing and verification of the hot water heater thermostat setting, without the necessity of unlocking and opening the protective apparatus.

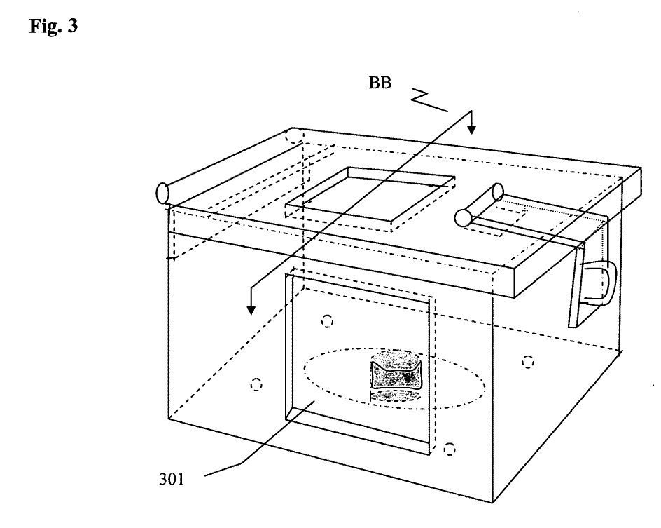

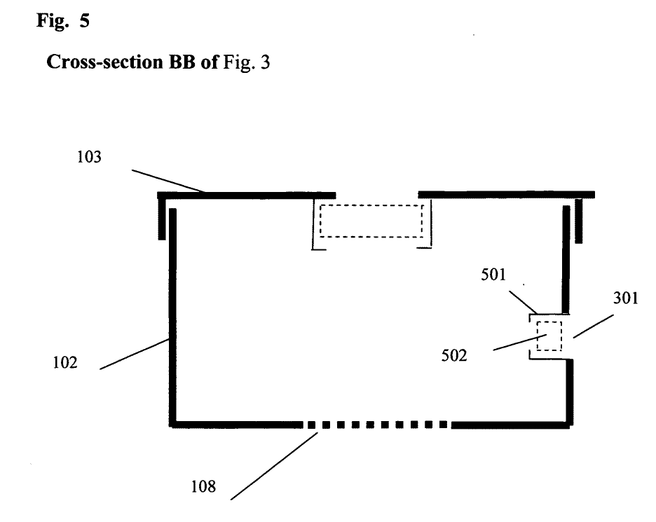

FIG. 3 shows the apparatus of FIG. 2, with the addition of a second “window” cut-out 301, in a side of the protective shell 102. The cross-section BB is shown in FIG. 5.

FIG. 5 shows the cut-out 301 in a side of the protective shell 102. There are retaining structural elements 501 are similar to that described in the above paragraph a second cut-out in the protective cover, placeably adapted to provide a view of whatever is seen through the first cut-out;

A first transparent window, 402 comprising a breakage-resistant material, firmably held in place, by means known in the art, to cover the second cut-out from inside the protective structure formed by the protective shell and the protective cover;

A third cut-out 301 in the protective shell 102, is placed so as to provide a entry of for ambient or other light to help the viewing of whatever may be seen through the first cut-out 108.

a second transparent window 502, comprising a breakage-resistant material, firmably held in place, by means known in the art, to cover the third cut-out 301 from inside the protective structure formed by the protective shell 102 and the protective cover 103.

The third cut-out 301, for the second window 502, in the range from 0.5 to 2 inches in either horizontal direction, or as a diameter, or as diameter, and with a second transparent window material ranging from these dimensions plus about 0.25 to 0.5 inches.

The second transparent window block 502 may range from ¼ inch to 1 inch of thickness. It is held in place by structural members 501, into which the block of window transparent material 502 may be slid.

The enclosing structural members 501 may be enclosing the block of window material 502 on three-sides, with a fourth enclosing member attached by screw(s) may be emplaced to secure the transparent window material 502 (adapted to be larger than the cut-out opening 301). Various methods of securing the transparent window material 502 are well known in the art and any such method may be used.

This second window allows for a better lighting of a hot water heater thermostat control for better viewing and verification. Where there is insufficient ambient light, a second window also provides for easier lighting and viewing, utilizing a flashlight, for example.

The detail of the staple 107 which may be welded to the protective shell 102 is shown in FIG. 8. The staple 107 is typically formed with an attachment plate 1071, which is then attached to the protective cover, adapted to be in alignment with the hinged 106 hasp 105, to form a lockable protective apparatus, preventing changing of the thermostat control on a hot water heater.

Although welding is a preferred method for attaching various elements of the apparatus together, riveting may also be used.

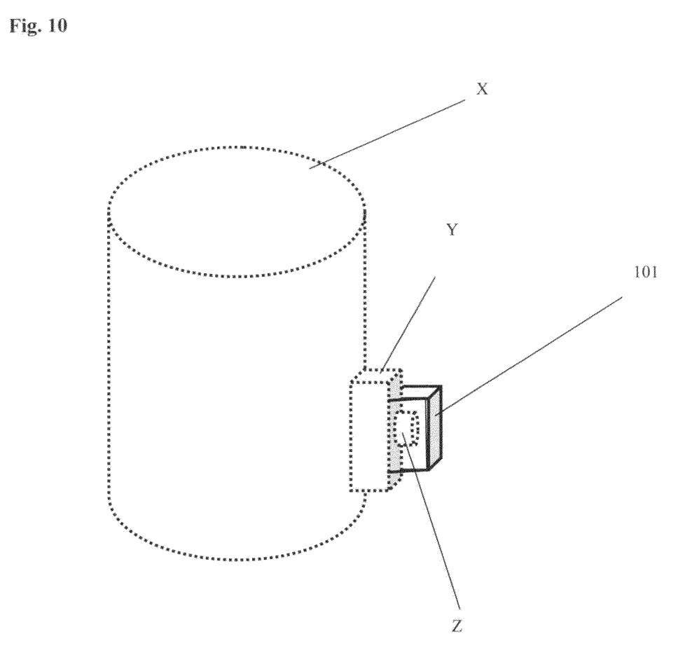

FIG. 10 shows the present invention 101 placed on a large hot-water heater X, on the flat part of the hot-water heater thermotat housing Y, over the hot-water temperature control knob Z.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention.

It is claimed that:

1. A scald-preventing protective apparatus, comprising:
a protective shell wherein the protective shell encloses all but a cut-out in a first surface, and an opening opposite the first surface of the protective shell which has a cut-out;
a protective cover wherein the protective cover is integrally attached to the protective shell by a first hinge and is adapted to cover the opening opposite the first surface with a cut-out and is adapted to be locked to the protective shell to form a completely protective enclosure;
the cutout in the first surface wherein the placement of the cutout is adapted to fit over a thermostat control knob protruding from a hot water heater; and
screw holes adapted for accommodating screws attaching the protective shell to a hot water heater wherein the screw holes are located within the volume of the protective shell and protective cover.

2. The scald-preventing apparatus of claim 1, further comprising:
a hasp wherein the hasp has a first hinge plate attached to the protective cover and a second elongated hinge plate conformed to a bent shape, wherein the second elongated hinge plate forms a main element of the hasp;
the bent shape adapted to conform to an elongation along the protective cover and an elongation at about a right angle to engagably meet a staple; and
a slot in the main element of the hasp engagable over the staple wherein the main element of the hasp and the staple, when fully engaged, form a pad-lockable structure.

3. The scald-preventing apparatus of claim 1, further comprising:
the cut-out in the range of 2.25 inches to 3.5 inches.

4. The scald preventing apparatus of claim 1, further comprising:
the protective shell and the protective cover made from metal.

5. The scald-preventing apparatus of claim 1, further comprising:
the protective shell and the protective cover made from steel.

6. The scald-preventing apparatus of claim 2, further comprising:
the protective shell being formed as faces of a rectangular solid without an sixth face wherein the sixth face is opposite to the cut-out; and
the dimensions of said rectangular solid ranging from 5 inches to 10 inches long, and 5.inches to 8 inches wide, and 1 inch to 5 inches high.

7. The scald-preventing apparatus of claim 2, further comprising:
A main element of the hasp bent to shape having an end that engages the staple and then bends outward for a distance from 0.25 inches to 0.5 inches.

8. A windowed scald-preventing protective apparatus, comprising:
a protective shell wherein the protective shell encloses all but a cut-out in a first surface, and an opening opposite the first surface of the protective shell which has a cut-out;
a protective cover wherein the protective cover is integrally attached to the protective shell by a first hinge and is adapted to cover the opening opposite the first surface with a first cut-out and is adapted to be locked to the protective shell to form a completely protective enclosure;
the cut-out in the first surface wherein the placement of the cutout is adapted to fit over a thermostat control knob protruding from a hot water heater;
screw holes adapted for accommodating screws attaching the protective shell to a hot water heater wherein the screw holes are located within the volume of the protective shell and protective cover;
the protective shell being formed as faces of a rectangular solid without an sixth face wherein the sixth face is opposite to the cut-out;
a protective cover formed as the sixth face of the faces of a rectangular solid;
a second cut-out in the protective cover, placeably adapted to provide a view of whatever is seen through the first cut-out;
a transparent window, comprising a breakage-resistant material, firmably held in place, by means known in the art, to cover the second cut-out from inside the protective structure formed by the protective shell and the protective cover;
a hasp wherein the hasp has a first hinge plate attached to the protective cover and a second elongated hinge plate conformed to a bent shape, wherein the second elongated hinge plate forms a main element of the hasp;
the bent shape adapted to conform to an elongation along the protective cover and an elongation at about a right angle to engagably meet a staple;
a slot in the main element of the hasp engagable over the staple wherein the main element of the hasp and the staple, when fully engaged, form a pad-lockable structure; and
the protective shell and the protective cover made from metal.

9. The windowed scald-preventing apparatus of claim 8, further comprising:
a transparent plastic as the breakage-resistant material.

10. The windowed scald-preventing apparatus of claim 9, further comprising:
cast acrylic plastic as the transparent plastic.

11. The windowed scald-preventing apparatus of claim 8, further comprising:
the first cut-out in the range of 2.25 inches to 3.5 inches; and
the second cut-out, for the first window, in the range 1 inches to 5 inches in either horizontal direction, or as a diameter, and with a first transparent window material ranging from these horizontal dimensions plus 0.25 to 0.5 inches, and with a the transparent window material ranging from 0.25 inches to 1 inch in thickness;

12. The windowed scald-preventing apparatus of claim 8, further comprising:
the protective shell and the protective cover made from steel.

13. The windowed scald-preventing apparatus of claim 8, further comprising:
the protective shell being formed as faces of a rectangular solid without an sixth face wherein the sixth face is opposite to the cut-out;
the dimensions of said rectangular solid ranging from 5 inches to 10 inches long, 5.inches to 8 inches wide, and 1 inch to 5 inches high; and
the protective cover having dimensions larger than the protective shell wherein the hinged cover is adapted to closely fit over the protective shell while remaining engagably movable with respect to the protective shell.

14. The windowed scald preventing apparatus of claim 8, further comprising:
a main element of the hasp bent to shape having an end that engages the staple and then bends outward for a distance from 0.25 inches to 0.5 inches

15. A double windowed scald-preventing protective apparatus, comprising:
a protective shell wherein the protective shell encloses all but a cut-out in a first surface, and an opening opposite the first surface of the protective shell which has a cut-out;
a protective cover wherein the protective cover is integrally attached to the protective shell by a first hinge and is adapted to cover the opening opposite the first surface with a first cut-out and is adapted to be locked to the protective shell to form a completely protective enclosure;
the cut-out in the first surface wherein the placement of the cutout is adapted to fit over a thermostat control knob protruding from a hot water heater;
screw holes adapted for accommodating screws attaching the protective shell to a hot water heater wherein the screw holes are located within the volume of the protective shell and protective cover;
the protective shell being formed as faces of a rectangular solid without an sixth face wherein the sixth face is opposite to the cut-out;
a protective cover formed as the sixth face of the faces of a rectangular solid/;
a second cut-out in the protective cover, placeably adapted to provide a view of whatever is seen through the first cut-out;
a first transparent window, comprising a breakage-resistant material, firmably held in place, by means known in the art, to cover the second cut-out from inside the protective structure formed by the protective shell and the protective cover;
a third cut-out in the protective shell, placeably adapted to provide a entry of ambient or other light to help the viewing of whatever may be seen through the first cut-out;
a second transparent window, comprising a breakage-resistant material, firmably held in place, by means known in the art, to cover the third cut-out from inside the protective structure formed by the protective shell and the protective cover;
a hasp wherein the hasp has a first hinge plate attached to the protective cover and a second elongated hinge plate conformed to a bent shape, wherein the second elongated hinge plate forms a main element of the hasp;
the bent shape adapted to conform to an elongation along the protective cover and an elongation at about a right angle to engagably meet a staple;
a slot in the main element of the hasp engagable over the staple wherein the main element of the hasp and the staple, when fully engaged, form a pad-lockable structure; and
the protective shell and the protective cover made from metal.

16. The double windowed scald-preventing apparatus of claim 15, further comprising:
a transparent plastic as the breakage-resistant material.

17. The double windowed scald-preventing apparatus of claim 16, further comprising:
cast acrylic plastic as the transparent plastic.

18. The windowed scald-preventing apparatus of claim 15, further comprising:
the first cut-out in the range of 2.25 inches to 3.5 inches,
the second cut-out, for the first window, in the range 1 inches to 5 inches in either horizontal direction, or as a diameter, and with a first transparent window material ranging from these horizontal dimensions plus 0.25 to 0.5 inches, and with a the transparent window material ranging from 0.25 inches to 1 inch in thickness; and
a third cut-out, for the second window, in the range from 0.5 to 2 inches in either horizontal direction, or as a diameter, or as diameter, and with a second transparent window material ranging from these dimensions plus about 0.25 to 0.5 inches, and with a depth ranging from about 0.25 to 0.5 inches.

19. The windowed scald-preventing apparatus of claim 8, further comprising:
the protective shell and the protective cover made from steel.

20. The windowed scald-preventing apparatus of claim 8, further comprising:
the protective shell being formed as faces of a rectangular solid without an sixth face wherein the sixth face is opposite to the cut-out;
the dimensions of said rectangular solid ranging from 5 inches to 10 inches long, 5.inches to 8 inches wide, and 1 inch to 5 inches high; and
the protective cover having dimensions larger than the protective shell wherein the hinged cover is adapted to closely fit over the protective shell while remaining engagably movable with respect to the protective shell;
